(19) United States
(12) Patent Application Publication
(10) Pub. No.: US 2009/0324805 A1
(43) Pub. Date: Dec. 31, 2009

(54) Optical monitor for thin film deposition using base stack admittance

(76) Inventor: William H. Southwell, Thousand Oaks, CA (US)

Correspondence Address: William H. Southwell, 1421 Feather Ave, Thousand Oaks, CA, 91360, US

(21) Appl. No.: 12/152,431

(22) Filed: May 14, 2008

Related U.S. Application Data
(60) Provisional application No. 60/931,509, filed on May 23, 2007.

(51) Int. Cl. C23C 14/54; G06F 17/00

(52) U.S. Cl. 427/10; 700/110; 700/108

(57) ABSTRACT

A method is provided for the determination of the time to terminate the deposition of an optical thin film using an exact model for the reflectance. This model is used to fit the reflectance measurements to determine the deposition rate, from which the time to deposit the entire layer is determined, as well as finding the admittance of the base stack at the beginning of the current layer. The layer deposition is terminated at the calculated time resulting in precise thickness control. This ability to fit the base admittance enables the determination of the reflection model parameters for each layer being deposited so that the accuracy of each layer is independent of previously deposited layers. This means that there is no build up of errors from layer to layer as the deposition progresses, enabling the deposition of coating designs with higher precision, including non periodic and non quarter wave designs.

### CROSS-REFERENCE TO RELATED APPLICATIONS

This application claims the benefit of provisional patent application No. 60/931,509 to William H. Southwell, filed May 23, 2007.

### STATEMENT REGARDING FEDERALLY SPONSORED RESEARCH OR DEVELOPMENT

This invention was made with Government support under contract DASG60-W9113M-06-C-0146 awarded by U.S. Army Space and Missile Defense Command. The Government has certain rights in the invention.

### REFERENCE TO SEQUENCE LISTING, A TABLE, OR A COMPUTER PROGRAM LISTING COMPACT DISC APPENDIX

“Not Applicable”

### FIELD OF THE INVENTION

The present invention relates to the process of depositing optical thin films and methods for controlling the thicknesses of the layers being deposited using a light beam monitor.

### BACKGROUND OF THE INVENTION

To fabricate high performance optical filters it is necessary to accurately deposit all the layers of the multilayer design with sufficient accuracy to obtain the desired performance. Many high performance optical filters require many layers with a wide range of thicknesses, sometimes 100 layers or more. Layer thickness monitoring is required to achieve the desired layer thicknesses as close as possible.

The current state of the art uses crystal monitors and optical monitors to control the layer thicknesses being deposited. Descriptions of these types of optical monitors are given in the references: Ronald R. Willey, “Practical Design and Production of Optical Thin Films,” second edition, Marcel Dekker, (2002); and H. A. Macleod, “Thin-Film Optical Filters,” second edition, Macmillan, (1986).

Both types of monitors are adequate for many of types of optical filters. Crystal monitors measure the mass being deposited on a small crystal. Such devices have the advantage of being precise, but they are not necessarily accurate. Furthermore they may fail during a deposition or become noisy and useless. Optical monitors that use a single wavelength have been successful in fabrication of WDM filters having very narrow bandwidth pass bands. This monitor is successful because of the error compensation properties it possesses when the layers are predominately all quarter wave optical thickness. Another type of optical monitor is the broad band optical monitor. It is successful in the deposition of rugate filters, (Southwell, et al., U.S. Pat. No. 5,000,575) but has not proven useful in the deposition of layered designs having many different thicknesses.

New design techniques in the last two decades have enabled the design of filters having higher performance; such as anti reflection coatings over very wide spectral bands, sharper and cleaner edge filters, and generally arbitrary spectral response filters. These designs consist of many layers, some thin, and generally all different thicknesses. The advantage of these designs is that better performance is seen. But the disadvantage is that they are more sensitive to thickness errors. Thus they require a more accurate thickness monitor. Crystal monitors do not have the required accuracy over the thick designs; the broad band optical monitor has not proven useful for these designs. Methods using a single line optical monitor have been investigated, but again have not been shown to produce these new design configurations.

Presented here is a new optical monitor which is capable of achieving higher layer thickness accuracy regardless of the nature of or number of the layers which have previously been deposited. It does not need new monitor chips even for thick coatings with many layers. Consequently, it may be used on a part eliminating the tooling factor, which is another source of error.

### BRIEF SUMMARY OF THE INVENTION

The basis of this new optical monitor is the use of base stack admittance updates along with an exact reflection model for the monitor signal. Monitoring a single layer on a known substrate is considerably easier that trying to extract optical parameter information from a multilayer stack. The base stack admittance provides an equivalent substrate for any succeeding layer. It is an observed fact that as a new layer is being deposited the optical monitor signal (reflectance or transmittance) is periodic in optical thickness. That means the trace on the monitor strip chart at any single wavelength will repeat itself every one half wave optical thickness. A key concept of this approach is to find the admittance, which is an equivalent substrate for each new layer. This is done by fitting the initial phase of the periodic optical signal for each new layer. This fitting of the monitor signal uses an exact stand-alone reflectance model to obtain base admittance and rate information. With current deposition rate information, the time to complete the layer is computed and the layer deposition is terminated at that time.

### BRIEF DESCRIPTION OF THE SEVERAL VIEWS OF THE DRAWING

In the drawings:

FIG. 1 is a schematic view of a vacuum deposition chamber used to deposit optical thin films.

FIG. 2 is a plot of an example optical monitor signal for a layer.

FIG. 3 is a flow logic flow diagram for a basic method of the present invention.

### DETAILED DESCRIPTION OF THE INVENTION

Consider the recursive formula for the calculation of amplitude reflectivity,

r=[rₐ+r_{b}exp(−i2φ)]/[1+rₐr_{b}exp(−i2φ)], (1)

where rₐ is the Fresnel reflection of the air side surface and r_{b} is the Fresnel reflection of the base side of the current layer with what is underneath it. The quantity r is the amplitude reflection from the air side of the entire structure including all multiple reflections. The layer phase thickness φ is at a wavelength λ and for the current layer with index n and thickness t,

φ=2πnt/λ. (2)

It is easy to calculate rₐ,

rₐ=(1−n)/(1+n), (3)

where n is the index of the current layer. When the layer is non-absorbing then rₐ is always real and always negative. The amplitude reflection on the base side of the current layer, r_{b} is complex in general, which we choose to write in complex polar form,

r_{b}=r_{b1}+ir_{b2}=ρ_{b}exp(iβ), (4)

where r_{b1} and r_{b2} are the real and imaginary parts of r_{b}. Knowing these we may obtain the polar components,

ρ_{b}=[r_{b1}²+r_{b2}²]½ (5)

β=arctan(r_{b2}/r_{b1}). (6)

The magnitude reflectivity ρ_{b} is real and always positive. It is assumed β ranges from minus π to plus π, −π<β≦π. Using this polar form of r_{b} in Eq. (1) we have,

r=[rₐ+ρ_{b}exp(i(β−2φ))]/[1+rₐr_{b}exp(i(β−2φ))]. (7)

Multiplying this by its complex conjugate gives the real reflectance R,

R=[rₐ²+ρ_{b}²+2rₐρ_{b} cos(β−2φ)]/[1+rₐ²ρ_{b}²+2rₐρb cos(β−2φ)]. (8)

For convenience we write this as,

R=[P₁+cos(β−2φ)]/[P₂+cos(β−2φ)]. (9)

The parameters P₁ and P₂ are given by,

P₁=[rₐ²+ρ_{b}²]/(2rₐρ_{b}), (10)

P₂=[1+rₐ²ρ_{b}²]/(2rₐρ_{b}). (11)

Equation (9), with (10) and (11), is the model for the optical monitor under consideration. R models the reflectance seen from light at any wavelength λ from the growing film. I now show how this expression is used to monitor thickness and index at normal incidence.

To use Eq. (9) one needs to know ρ_{b} and β as we start deposition of a new layer. The deposition starts with the first layer on the substrate. In that case ρ_{b} and β are known,

r_{b}=[n−nₛ]/[n+nₛ]. (12)

When n and nₛ are real, then ρ_{b}=r_{b}² and β=0 or π depending on whether n<nₛ or not. After the first layer one could use the recursive Eq. (1) to numerically compute the r_{b} for the next layer using the layer thickness and index. Another alternative is to use admittance beginning with the substrate. In general, the base amplitude reflectivity is given by,

r_{b}=[n−y]/[n+y], (13)

where y is the admittance at the surface, and is in general complex, y=y₁+iy₂. Admittance of the substrate is just the refractive index of the substrate. To derive the update equations for admittance after the deposition of a single layer, we have the B, C matrix equation,

$$\text{?} = \text{?} \text{?} \\ \text{?} \text{indicates text missing or illegible when filed} \qquad ( 14 )$$

The updated admittance is computed from

y=C/B. (15)

But there is another more elegant way. After the deposition of the first layer and the computation of the amplitude reflectivity using Eq. (7), one then uses the following well-known equation for this same r,

r=[1−y][1+y]. (16)

This equation is easily inverted to yield the admittance y as a function of r,

y=[1−r]/[1+r]. (17)

Notice the symmetry between Eqs. (16) and (17). Equations (17) and (7) give the admittance update equations,

y₁=n(1−ρ_{b}²)/[1+ρ_{b}²+2ρ_{b} cos α] (18)

y₂=−2nρ_{b} sin α/[1+ρ_{b}²+2ρ_{b} cos α], (19)

where

α=β−2φ. (20)

At this point the first layer is deposited and the admittance is updated. With the new admittance one is able to compute the new r_{b} through the relation,

r_{b}=ρ_{b}exp(iβ)=[n−y]/[n+y], (21)

where n now is the index of the next layer to be deposited. Equation (21) is a complex equation which may easily be solved to give us the new base reflectance,

ρ_{b}={[(n−y₁)²+y₂²]/[(n+y₁)²+y₂²]}^{1/2}, (22)

β=arctan(−2ny₂/(n²−y²)). (23)

When the layer being deposited has a non-zero extinction coefficient, then n in these equations become complex with the real part of n being the refractive index and the imaginary part being −k, the negative extinction coefficient. (The equations in that case are straight forward to derive and apply. Thus, this method applies to the deposition of metals and semiconductors as well as dielectrics.)

This enables the use of Eq. (8) to be the model for the deposition of the next layer. The same procedure is now used for any succeeding layer. When a layer is finished, update the base stack admittance using Eqs. (18) and (19), then form the new base reflectivity from Eqs. (22) and (23).

### DETAILED DESCRIPTION OF THE DRAWINGS

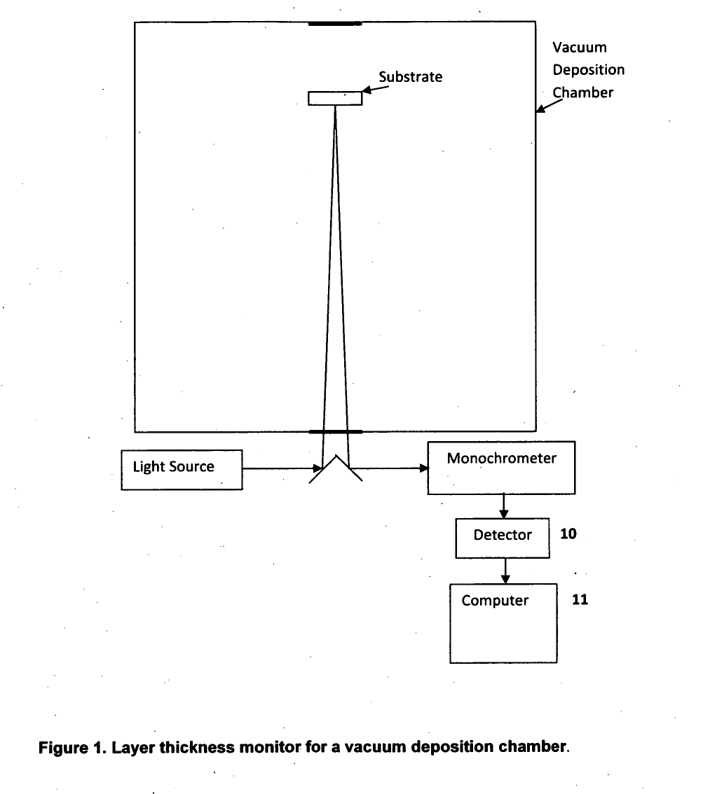

The filter substrates are typically placed near the top of the chamber as shown in FIG. 1. An optical beam is directed onto one of the filters being deposited and then directed to an optical filter or monochrometer which selects the monitor wavelength. The beam is then directed to the detector 10 where the light intensity is measured and sent to a computer. The computer also records the time at which the measurement was made.

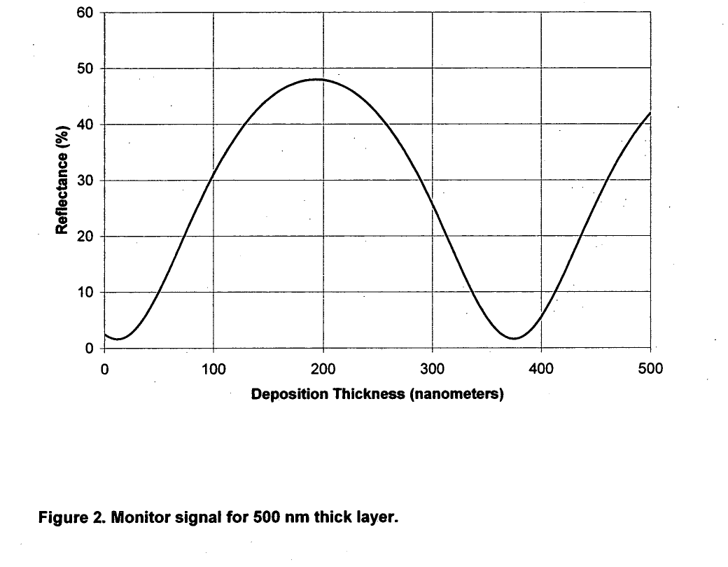

To get a feeling for the role of beta, shown in FIG. 2 is a plot of the reflectance monitor model Eq. (9) with β=11.5°. This is an exact model.

A few features of the reflectance model Eq. (9) are evident with FIG. 2,
If beta=0, this signal would start at the bottom of the cycle.
The pattern is periodic with increasing thickness.
For a dielectric substrate beta=0 or 180° and the signal starts moving up or down depending on n>ns, as so starts at an Rₘᵢₙ or Rₘₐₓ.
Beta depends on wavelength so this pattern will have different starting points at different wavelengths
A turning point may occur well before a quarter wave thickness is deposited.
The reflectance amplitude Rₘᵢₙ and Rₘₐₓ depend on admittance and the index of the depositing layer and the monitor wavelength. Some wavelengths will show more “action” than others.

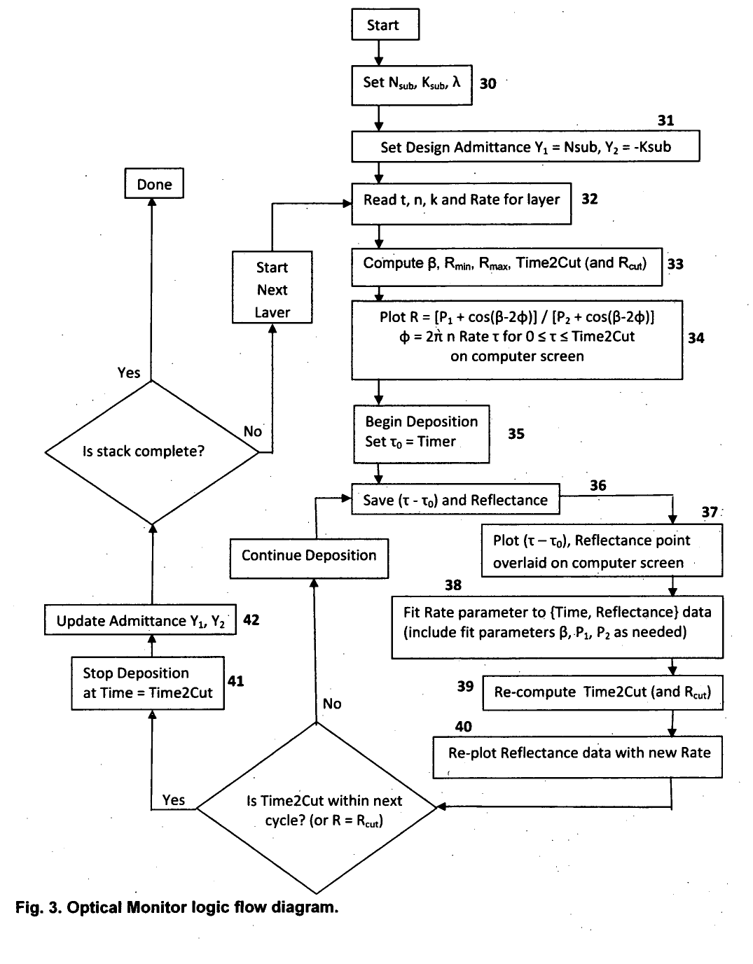

A step by step procedure of the implementation of the preferred embodiment of the invention is given in FIG. 3. The deposition of a filter begins with the start box at the top of the figure. Thereafter the events proceed along the given arrows. The admittance is initiated at the substrate and then updated at the end of each layer. Knowing the admittance at the beginning of each layer is like knowing an equivalent or effective substrate upon which the current layer is being deposited. We use this admittance to calculate the constants of the exact model for the reflectance occurring with the current depositing layer. The model reflectance is plotted on the computer screen as shown in FIG. 2. As real reflectance measurements are made they are also plotted as points on the screen. The operator is able to see changes in rates which affect the determination of the termination point of the deposition.

The basic process of the present invention is illustrated in the flow diagram boxes of FIG. 3. Fabricating a thin film filter begins by setting up the monitor conditions such as specifying 30 the substrate refractive index and extinction coefficient and initializing the admittance 31, which is the complex refractive index of the substrate. Starting with layer 1 the design parameters for each layer 32 and the anticipated deposition rate are read in from computer memory. The base admittance is then used to determine the parameters for the reflectance model 33 as well as the deposition time, Time2Cut, and the value of reflectance R_{cut} at the end of the layer. The reflectance model is then plotted on the computer screen. This enables the operator to see what the monitor signal will be for that layer. The deposition time is also displayed in minutes and seconds. This time ticks down as the layer grows. As the deposition proceeds improved rate estimates are obtained.

With these preliminary computations being made the deposition 35 begins and the beginning time is noted using the internal computer dock. Reflectance values from the detector 10 are accumulated 36 by the computer 11 and then are plotted 37 as points on the computer screen. This process enables the operator to visually detect any abnormalities of the deposition process. When all is going well the measured data points will lie on the previously plotted 34 reflectance model. As the deposition precedes the computer fits 38 the data already accumulated to refine the parameters of the model. The deposition rate is the most important parameter of this fit. From the rate estimates, the computer recalculates 39 the deposition termination time, as well as the cut reflectance, as displays them on the screen. With new model parameters the data points are re-plotted on the screen 40. Only the rate parameter is used to adjust the plotted measurement points, whereas the other model parameters influence the re-plotting of the model.

The deposition continues until the current cut time is achieved at which time the deposition is stopped 41. In an alternative embodiment, the layer deposition is terminated when the reflectance reaches the R_{cut} value predicted by the best fit model. With the layer deposition completed, the admittance is updated 42 using the admittance update Equations (14) and (15). This new admittance now becomes the base admittance for the next layer. The base stack admittance acts like a substrate for the deposition of the next layer.

If the stack deposition is not completed, then the next layer design and material rate information is read from file 32 and the process is repeated.

### DETAILED DESCRIPTION OF THE INVENTION

A model for the monitor reflectance at any wavelength has been established. Next is shown how to extract layer thickness and index during the deposition so as to enable an accurate layer termination point. During the deposition the phase thickness is increasing. At each reflection measurement the time are reflection are recorded. A collection of these points is them compared or fit to the model. The thickness is related to the deposition time through the deposition rate. This comparison or fitting to make the data fit to the model determines the deposition rate. The deposition rate is the most important parameter to fit. With an accurate rate, the time to terminate may be computed for a specific layer design thickness. This is one embodiment of this invention. Another is to determine the current layer thickness from the measurements and then terminate when the thickness reaches the design value. The layer thickness is determined from the time measurement of the latest measurement, thickness=rate times the deposition time. The phase thickness φ=2πnt/λ contains the optical thickness nt. If the layer material has been previously characterized then its index is known and physical thickness at the last measurement could be determined from an extraction of the last phase value.

Although beta has been established before the layer deposition begins, from knowing the base admittance and the index of the new layer, it is also an easy matter to include it in the fit of the monitor reflectance. Other parameters of interest in the fit are the turning point maxima and minima reflectance values. These are related to our model parameters P1 and P2 through the relations,

Rₘₐₓ=[P₁−1]/[P₂−1] (24)

Rₘᵢₙ=[P2+1]/[P2+1]. (25)

It may appear from Eq. (8) that these equations are backward. Since rₐ is always negative and ρ_{b} is always positive, then from Eqs. (9) and (10) P₁ and P₂ are always negative. Thus subtracting the cosine term produces a higher reflectance. The numerator and denominator in these equations are always negative so that the reflectance is always positive.

We may include Rₘₐₓ and Rₘᵢₙ as fit parameters of our R versus time plot. This will correct for changes in the uncertainties or drifts of the reflectance values. Equations (24) and (25) may be inverted to yield,

P₂=[Rₘₐₓ+Rₘᵢₙ−2]/[Rₘₐₓ−Rₘᵢₙ] (26)

P₁=Rₘₐₓ[P₂−1]+1. (27)

The fitting procedure also reduces the effect of random noise of the reflection measurements.

The following four parameters may be used to fit the R versus time data to the monitor model. They are
Rate
Beta
Rₘₐₓ
Rₘᵢₙ

Note that this list does not include current thickness. But the thickness at any time is determined from knowing the deposition rate and the deposition time.

Thickness=Rate(time−Start time). (28)

This is the thickness for the current layer, not the total optical or physical thickness. This monitor is concerned only with the current layer, even though we obtain the reflectance from the entire stack. By updating the admittance we have a new equivalent substrate on which to deposit the new layer.

### Index Determination

Once we have the four fit parameters of the monitor data we have established all the parameters of the model. This permits the determination also of the refractive index of the deposited layer. It had been thought that one could not obtain both physical thickness and index from a reflectance measurement at normal incidence. With ellipsometry one can get both thickness and index of a layer but in that case one uses a high angle of incidence and both polarizations are used. In effect the ellipsometer has two bits of data which can produce two outputs. But at normal incidence both polarizations are the same spectrally, so there is only one bit of information.

Use of the optical monitor of this invention would ordinarily not require the extraction of the refractive index of the depositing layer since deposition materials are generally well known and their properties may be determined in prior calibration runs. However, there are situations where deposition materials are mixed and the knowledge of the refractive index is of interest. This may be done with the present invention. But bear in mind that the index extraction is more sensitive to monitor signal errors than is the thickness, so the refractive index results are less reliable. Nevertheless, the method is presented here for cases where absolute reflectance measurements are available.

In principle, when the base admittance is known and the monitor supplies absolute reflectance measurements, then the optical thickness may be deduced by an inversion of our reflectance model Eq. (9). This means the optical thickness is known from each new reflectance measurement. This is a powerful consequence of the admittance and reflectance model approach of this invention. And indeed, that is another embodiment of this invention. However, it is not the preferred embodiment because in practice the reflectance data will have errors. What I submit as the preferred embodiment is the use of the admittance and reflectance model which includes the fitting of the parameters in a process that yields the thickness, specifically, the optical thickness, in a fashion that is robust to measurement errors.

Next the method for refractive index extraction is described. In this case it is assumed the index is not known before deposition. The refractive index is determined from the fit to the reflectance data as it evolves. The index information is obtained from the fit for Rₘₐₓ and Rₘᵢₙ. This gives the model parameters P₁ and P₂ through Eqs. (26) and (27). But P₁ and P₂ are related to rₐ and ρ_{b} through Eqs. (10) and (11). Inverting these equations is difficult. We will not go through the details here. We have obtained the solutions,

C₁=P₁±[P₁²−1]^{1/2} (29)

C₂=P₂±[P₂²−1]^{1/2}. (30)

Then,

ρ_{b}²=C₁C₂, (31)

rₐ²=C₂/C₁. (32)

With this elegant solution, we obtain,

rₐ=−[C₂/C₁]^{1/2}, (33)

n=[1−rₐ]/[1+rₐ]. (34)

which is the refractive index of our depositing layer. There is a difficulty in determining which sign to use in the plus or minus cases. I have not as yet determined the rule which applies in every case. It is of interest to observe that C₁ and C₂ are always negative since P₁ and P₂ are always negative. Since rₐ also is always negative, the negative sign on the square root in Eq. (33) must be used.

I have performed numerical studies of these solutions for a wide variety of situations, high and low substrate index, high and low layer refractive index, different layer thicknesses, and different beta values. I have made an important interesting discovery. I have fixed the use of the plus sign in Eqs. (29) and (30) as that works well most of the time. When doing so and when Eq. (34) does not yield the correct layer index, then the square root of ρ_{b}² is the correct answer. This result is astonishing. More analysis may help understand R. Nevertheless, we use this fortuitous fact to establish a test from which is obtained the correct index in all cases.

### Discussion

In summary the equations have been set down for a new optical monitor. This new monitor enables complicated coating designs, not just quarter wave stacks, to be deposited.

A property of this invention which uses a base admittance to form an exact reflection model for each layer being deposited is that the accuracy of each layer is independent of previously deposited layers. This means that there is no build up of errors from layer to layer as the deposition progresses. Crystal monitors have this property and another optical monitor has been developed which also has this property (A. V. Tikhonravov and M. K. Trubetskov, “Elimination of cumulative effect of thickness errors in monochromatic monitoring of optical coating production: theory,” Applied Optics Vol. 46, p. 2084-2090 (2007)). The technique of Tikhonravov and Trubetskov, however, requires two reflection turning points in the monitor signal as well as requiring precise absolute reflection measurements, both of which are not necessary with the technique of the present invention.

Another novel aspect of this invention which uses a base admittance to form an exact reflection model is that the layer deposition point may be determined even in the presence of noise in the monitor signal or in the deposition rates. Correct thicknesses are determined even when there is random noise or a systematic offset error in the reflectance. The rate variable in the fit in the model adjusts the scale factor on the horizontal axis. The rate may be determined well even when there are vertical (reflectance) offsets. Furthermore, the least squares fitting of the reflectance data tends to negate the effects of random reflectance noise. The parameters of the reflection model include the values of Rₘᵢₙ and Rₘₐₓ, which when they are included in the variable list the effects systematic or reflectance offset errors are reduced or eliminated. Fitting beta, which is the starting phase of the periodic function for the reflectance, fixes the start point of the model. When turning points are included in the monitor signal, then the uncertainty in the rate fit is further reduced. However, the rate variable may be fit even without the presence of a turning point.

There are several embodiments of this invention which may become evident to those skilled in the art of optical monitoring. For example, the selection of the monitoring wavelength may be determined to enhance the swing of the monitor signal. Monitoring wavelengths may differ for different layers. Indeed, multiple wavelengths may be used with admittance tables computed for each one, enabling improved performance over wider spectral regions.

The preferred embodiment of this invention uses a reflectance monitor signal. It is also possible to use transmittance as the monitor signal.

These and other such embodiments occurring to those skilled in the art are all considered within the scope of this invention.

The preferred embodiment of this invention consists of the process of determining the time at which the deposition is to be terminated. With this approach d does not matter if the termination time occurs at some point between the collection of data points. This is an issue for some monitors when thickness is being monitored and the target thickness will occur before the next data point is collected. Furthermore, another embodiment of the present invention is to compute the reflectance level at the end of the layer from the current best fit model (Eq. (9)) and to cut the deposition when that monitor signal is achieved.

It is preferred to have available both the Time2Cut, which determines the clock time when the layer is finished, and also the Rcut, which is the reflectance value of the monitor when the layer will achieve its correct thickness. Normally, one would use the time approach to stop deposition, but when for some reason the deposition had to be interrupted which then violates the assumption of constant rate, then the layer may be terminated when deposition resumes using the specified cut reflectance value.

1. A method for monitoring and controlling deposition thicknesses of optical thin films consisting of an optical beam directed to an optical part being deposited and its reflectance or transmittance being directed to a sensor measuring its intensity changes as the deposition progresses and such changes being processed to predict when the specified layer thickness will be achieved or when the layer deposition should be terminated.

2. A method for controlling deposition thicknesses of optical thin films consisting of an optical beam directed to an optical part being deposited and its reflectance or transmittance being directed to a sensor measuring its intensity changes as the deposition progresses and such changes being collected by a computer over the deposition time and such data being compared to a reflectance model given by
R=[P₁+cos(β−2φ)]/[P₂+cos(β−2φ)]
where P₁ and P₂ are constants for each layer, q=2πnt/λ is the growing layer phase thickness, n is the refractive index of the depositing layer, t is the physical thickness of the deposited layer, λ is the monitor wavelength, and β is the beginning phase of this periodic reflectance function, and the parameters of the model being fit to the measured reflectance, from which in turn a determination is made for when the desired thickness is achieved.

3. The method of claim 2 wherein the thickness t is further modeled as
t=Deposition Rate times Deposition Time,
where the deposition time is assigned a value determined as the time since the beginning of the deposition of the layer at which each reflectance measurement is made and where the deposition rate is determined by fitting the collection of measured reflectance and corresponding times to the model, such fit deposition rate is used to determine the time when the deposition should cease according to the relation,
Total Deposition Time=Target Layer Thickness/Deposition Rate,
where the Deposition Rate is determined by fitting the monitor signal and time measurements to the reflectance model and where the computed Total Deposition Time is used to determine when the deposition should cease to achieve the target layer thickness, which Total Deposition Time may be updated as the layer deposition progresses and better values for the Deposition Rate emerge from the fitting the measurements.

4. The method of claim 2 wherein the parameters of the model are determined numerically such as by using least squared techniques.

5. The method of claim 2 wherein the optical admittance Y is being updated for each deposited layer starting from the admittance of the substrate Y=N_{sub}−iK_{sub}, where N_{sub} and K_{sub} are the refractive index and extinction coefficient of the monitor substrate and where the updated admittance is used to generate a plot of the expected monitor signal for the next layer and where the monitor signal measurement points are also put on this plot on the computer screen, which enables the coating deposition operator to quickly discern deposition rate differences and abnormal functioning of the deposition system or the software, thereby being able to prevent loss of coating runs.

6. The method of claim 2 wherein the parameters of the monitor signal fit include the maxima and minima of the monitor signal Rₘₐₓ and Rₘᵢₙ to adjust the P₁ and P₂ parameters of the model according to the relations,
P₂=(Rₘₐₓ+Rₘᵢₙ−2)/(Rₘₐₓ−Rₘᵢₙ)
Pᵢ=Rₘₐₓ(P₂−1)+1,
such that the rate and β parameters may be determined even in the presence of errors in the reflectance.

7. An optical monitor system for controlling deposition thicknesses of optical thin films consisting of a light source of wavelength λ forming an optical beam directed to an substrate being deposited and its reflectance or transmittance being directed to a sensor measuring its intensity changes as the deposition progresses and such changes being collected by a computer over the deposition time and such data being compared to a reflectance model given by
R=[P₁+cos(β−2φ)]/[P₂+cos(β−2φ)]
where P₁ and P₂ are constants for each layer, φ=2πnt/λ is the growing layer phase thickness, n is the refractive index of the depositing layer, t is the physical thickness of the deposited layer, λ is the monitor wavelength, and β is the beginning phase of this periodic reflectance function, and the parameters of the model being fit to the measured reflectance, which in turn a determination is made for when the desired thickness is achieved.

8. The system of claim 7 wherein the thickness t is further modeled as
t=Deposition Rate times Deposition Time,
where the deposition time is assigned a value determined as the time since the beginning of the deposition of the layer at which each reflectance measurement is made and where the deposition rate is determined by fitting the collection of measured reflectance and corresponding times to the model, such fit deposition rate is used to determine the time when the deposition should cease according to the relation,
Total Deposition Time=Target Layer Thickness/Deposition Rate,
where the Deposition Rate is determined by fitting the monitor signal and time measurements to the reflectance model and where the computed Total Deposition Time is used to determine when the deposition should cease to achieve the target layer thickness, which Total Deposition Time may be updated as the layer deposition progresses and better values for the Deposition Rate emerge from the fitting the measurements.

9. The system of claim 7 wherein the parameters of the model are determined numerically such as by using least squared techniques.

10. The system of claim 7 wherein the optical admittance Y is being updated for each deposited layer starting from the admittance of the substrate Y=N_{sub}−iK_{sub}, where N_{sub} and K_{sub} are the refractive index and extinction coefficient of the monitor substrate and where the updated admittance is used to generate a plot of the expected monitor signal for the next layer and where the monitor signal measurement points are also put on this plot on the computer screen, which enables the coating deposition operator to quickly discern abnormal functioning of the deposition system or the software, thereby being able to prevent loss of coating runs.

11. The system of claim 7 wherein the parameters of the monitor signal fit include the maxima and minima of the monitor signal Rₘₐₓ and Rₘᵢₙ to adjust the P₁ and P₂ parameters of the model according to the relations,
P₂=(Rₘₐₓ+Rₘᵢₙ−2)/(Rₘₐₓ−Rₘᵢₙ)
P₁=Rₘₐₓ(P₂−1)+1,
such that the rate and β parameters may be determined even in the presence of errors in the reflectance.
